(19) United States
(12) Patent Application Publication
(10) Pub. No.: US 2013/0120048 A1
(43) Pub. Date: May 16, 2013

(54) DC OFFSET CANCELATION CIRCUIT

(71) Applicants: Yoo Sam NA, Seoul (KR); Hyun Hwan Yoo, Suwon (KR)

(72) Inventors: Yoo Sam NA, Seoul (KR); Hyun Hwan Yoo, Suwon (KR)

(73) Assignee: SAMSUNG ELECTRO-MECHANICS CO., LTD.

(21) Appl. No.: 13/619,117

(22) Filed: Sep. 14, 2012

(30) Foreign Application Priority Data
Nov. 11, 2011 (KR) 10-2011-0117401

(51) Int. Cl. H03L 5/00

(52) U.S. Cl. 327/307

(57) ABSTRACT

There is provided a DC offset cancellation circuit including: a capacitor circuit unit including at least one capacitor connected between an input terminal and an input of an amplifier; a MOSFET circuit unit including a plurality of MOSFETs connected in series between a first connection node connected to a predetermined one of both terminals of the capacitor circuit unit and a ground and operating in a linear region; and a switching circuit unit including a plurality of switch elements for selecting several MOSFETs previously selected from among the plurality of MOSFETs of the MOSFET circuit unit, respectively.

### CROSS-REFERENCE TO RELATED APPLICATIONS

This application claims the priority of Korean Patent Application No. 10-2011-0117401 filed on Nov. 11, 2011, in the Korean Intellectual Property Office, the disclosure of which is incorporated herein by reference.

### BACKGROUND OF THE INVENTION

1. Field of the Invention

The present invention relates to a DC offset cancellation circuit applicable to a direct conversion receiver (DCR) system and which can be implemented as an integrated circuit (IC) by using a resistor in a linear region of a MOSFET, and can easily select a pass frequency.

2. Description of the Related Art

In general, a DC offset in a direct conversion structure of a communications system may negatively affect signals and should be solved. A DC offset is generated in the process of converting an RF signal into a baseband signal, acting as in-band interference.

In particular, in a case in which a low noise amplifier (LNA)/mixer is simultaneously fabricated with an oscillator such as in a DVB-S system, or the like, isolation characteristics are degraded, and the DC offset becomes severe due to phenomena such as substrate coupling, ground bounce, bond wire radiation, capacitive and magnetic coupling, and the like.

Thus, a DC offset cancellation circuit for canceling the DC offset is required.

In an existing communications system, a DC offset cancellation circuit is positioned in a front stage of an amplifier. The DC offset cancellation circuit includes a CR high pass filter including a capacitor and a resistor, a feedback type DC offset cancellation circuit, a forward-type DC offset cancellation circuit, and the like.

First, in the CR high pass filter, requiring a low frequency, a resistance value may be implemented as a transistor so as to be integrated.

Here, a cut-off frequency Fc is defined as ‘1/(2πRC)’, and in order to cancel a low frequency DC component, a capacitor having a high capacitance value should be used, making it difficult to implement an integrated circuit.

Next, in the feedback type DC offset cancellation circuit, a high frequency component of a signal output from an amplifier is removed by a high pass filter, and then, a DC component is subtracted from an input signal, thus canceling a DC offset.

In the feedback type DC offset cancellation circuit, in order to implement a feedback circuit and a circuit for subtracting a DC offset as digital circuits, a conversion circuit such as an A/D converter or a D/A converter is required, increasing the area occupied by the circuit. Also, even when a feedback circuit is implemented as an analog circuit without the A/D converter or the D/A converter, a complicated analog circuit is implemented, increasing the area of the circuit as much.

Also, in terms of the characteristics of the feedback structure, current consumption and a chip size are increased.

The forward-type DC offset cancellation circuit has a structure in which signals are allowed to pass through two paths to combine outputs inversely. In such a structure, one path has a form of the original amplifier, while the other path has a form of an amplifier having a very low cut-off frequency.

Also, in the forward-type DC offset cancellation circuit, when two outputs are inversely combined, components having a frequency equal to or lower than the cut-off frequency cancel out and only components having a frequency higher than the cut-off frequency are output.

Like the forward-type DC offset cancellation circuit, the forward-type DC offset cancellation circuit requires a conversion circuit such as an A/D converter or a D/A converter in order to implement a forward circuit and a circuit for subtracting a DC offset as digital circuits, the area occupied by the circuit is increased, and even when an analog feedback circuit is implemented without an A/D converter or a D/A converter, a complicated analog circuit is required to be implemented, increasing the area of the circuit as much.

As described above, when the DC offset cancellation structure using a high pass filter is employed in the direct conversion system, the values of a capacitor and a resistor that decide (or control) the cut-off frequency of the high pass filter must be great to obtain frequency characteristics close to a DC, but it is difficult to increase the size of the resistor or the capacitor unlimitedly due to the limited chip size.

### SUMMARY OF THE INVENTION

An aspect of the present invention provides a DC offset cancellation circuit applicable to a direct conversion receiver (DCR) system and which can be implemented as an integrated circuit (IC) by using a resistor in a linear region, and can easily select a pass frequency.

According to an aspect of the present invention, there is provided a DC offset cancellation circuit including: a capacitor circuit unit including at least one capacitor connected between an input terminal and an input of an amplifier; a metal-oxide-semiconductor field effect transistor (MOSFET) circuit unit including a plurality of MOSFETs connected in series between a first connection node connected to a predetermined one of both terminals of the capacitor circuit unit and a ground and operating in a linear region; and a switching circuit unit including a plurality of switch elements for selecting several MOSFETs previously selected from among the plurality of MOSFETs of the MOSFET circuit unit, respectively.

The MOSFET circuit unit may include a main MOSFET and first to nth MOSFETs connected in series between the first connection node and the ground, and the main MOSFET and the first to nth MOSFET may be set to operate in a linear region by a bias voltage.

The switching circuit unit may include first to nth MOS switches for selecting the first to nth MOSFETs of the MOSFET circuit unit, and each of the first to nth MOS switches may be connected between a drain and a source of each of the first to nth MOSFETs.

According to another aspect of the present invention, there is provided a DC offset cancellation circuit including: a capacitor circuit unit including at least one capacitor connected between an input terminal and an input of an amplifier; a MOSFET circuit unit including a plurality of MOSFETs connected in series between a first connection node connected to one of both terminals of the capacitor circuit unit and the ground and operating in a linear region; a switching circuit unit including a plurality of switch elements for selecting several MOSFETs previously selected from among the plurality of MOSFETs of the MOSFET circuit unit, respectively; and a switching controller controlling ON/OFF switching of the plurality of switch element of the switching circuit unit.

The MOSFET circuit unit may include a main MOSFET and first to nth MOSFETs connected in series between the first connection node and the ground, and the main MOSFET and the first to nth MOSFET may be set to operate in a linear region by a bias voltage.

The switching circuit unit may include first to nth MOS switches for selecting the first to nth MOSFETs of the MOSFET circuit unit, and each of the first to nth MOS switches may be connected between a drain and a source of each of the first to nth MOSFETs.

The switching controller may generate first to nth control signals for controlling the first to nth MOS switches of the switching circuit unit and provide the corresponding control signal to each of the first to nth MOS switches of the switching circuit unit.

The main MOSFET may be configured as an N channel MOSFET having a drain connected to the first connection node, a gate receiving the bias voltage, and a source. The first to nth MOSFETs may be connected in series between the source of the main MOSFET and the ground, and the first to nth MOSFETs may be configured as N channel MOSFETs, respectively.

The first to nth MOSFETs may be connected in series between the first connection node and the main MOSFET, and the first to nth MOSFETs may be configured as N channel MOSFETs, respectively. The main MOSFET may be configured as an N channel MOSFET having a drain connected to a source of the nth MOSFET, a gate receiving the bias voltage, and a source connected to the ground.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic block diagram of a DC offset cancellation circuit according to an embodiment of the present invention.

FIG. 2 is a view showing an implementation example of the DC offset cancellation circuit of FIG. 1.

FIG. 3 an equivalent resistance graph of a MOSFET in a linear region in the DC offset cancellation circuit according to an embodiment of the present invention.

FIG. 4 is a view showing a first operation of the DC offset cancellation circuit of FIG. 2.

FIG. 5 is a view showing a second operation of the DC offset cancellation circuit of FIG. 2.

FIG. 6 is a view showing a third operation of the DC offset cancellation circuit of FIG. 2.

### DETAILED DESCRIPTION OF THE INVENTION

Embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like components.

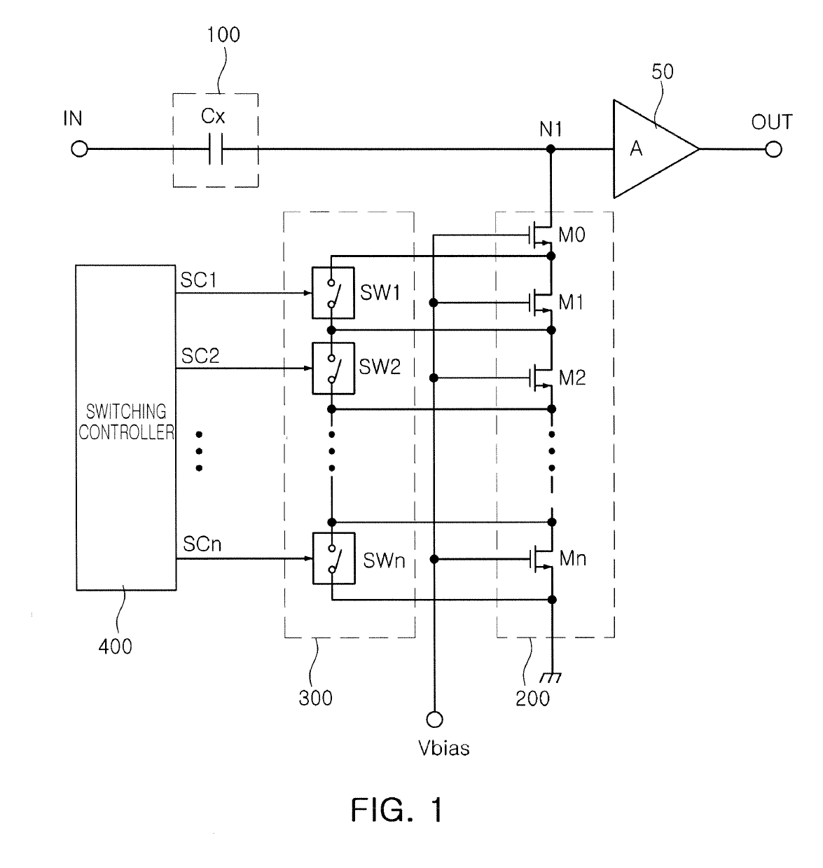

FIG. 1 is a schematic block diagram of a DC offset cancellation circuit according to an embodiment of the present invention.

With reference to FIG. 1, a DC offset cancellation circuit according to an embodiment of the present invention may include: a capacitor circuit unit 100 including at least one capacitor connected between an input terminal IN and an amplifier 50, a MOSFET circuit unit 200 including a plurality of MOSFETs connected in series between a first connection node N1 connected to one of both terminals of the capacitor circuit unit 100 and a ground and operating in a linear region, and a switching circuit unit 300 including a plurality of switch elements for selecting several MOSFETs previously selected from among the plurality of MOSFETs of the MOSFET circuit unit 200, respectively.

Also, the DC offset cancellation circuit according to an embodiment of the present invention may further include a switching controller 400 controlling ON/OFF switching of the plurality of switch elements of the switching circuit unit 300.

Referring to an operation of the DC offset cancellation circuit according to an embodiment of the present invention, the capacitor circuit unit 100 includes at least one capacitor connected between the input terminal IN and the input of the amplifier 500 to provide pre-set capacitance Cx.

Here, the switching controller 400 may control ON/OFF switching of the plurality of switch elements of the switching circuit unit 300.

The switching circuit unit 300 includes a plurality of switch elements for selecting several MOSFET previously selected from among the plurality of MOSFETs of the MOSFET circuit unit 200, respectively. The plurality of switch elements perform switching operations under the control of the switching controller 400.

The MOSFET circuit unit 200 includes a plurality of MOSFETs connected between the first connection node connected to one of both terminals of the capacitor circuit unit 100 and a ground and operating in a linear region. According to the switching operation of the switching circuit unit 300, the number of MOSFETs to be connected between the first connection node N1 and the ground, among the plurality of MOSFETs, is determined to provide equivalent resistance Rx determined by the connected MOSFETs.

Accordingly, a cut-off frequency (Fc=1/(2πRx*Cx)) is determined by the capacitance Cx of the capacitor circuit unit 100 and the equivalent resistance Rx of the MOSFET circuit unit 200.

With reference to FIG. 1, the MOSFET circuit unit 200 includes a main MOSFET M0 and first to nth MOSFETs M1 to Mn connected in series between the first connection node N1 and the ground. The main MOSFET M0 and the first to nth MOSFETs M1 to Mn may be set to operate in a linear region by a bias voltage Vbias.

Here, the switching circuit unit 300 includes first to nth MOS switches SW1 to SWn for selecting the first to nth MOSFETs M1 to Mn of the MOSFET circuit unit 200. The first to nth MOS switches SW1 to SWn are connected between drains and sources of the first to nth MOSFETs M1 to Mn, respectively. Each of the first to nth MOS switches SW1 to SWn may select each of the first to nth MOSFETs M1 to Mn.

For example, when the first MOS switch SW1 is turned off, the first MOSFET M1 is selected, and when the first MOS switch SW1 is turned on, the first MOSFET M1 is not selected. Also, when the second MOS switch SW2 is turned off, the second MOSFET M2 is selected, and when the second MOS switch SW is turned on, the second MOSFET M2 is not selected.

When the nth MOS switch SWn is turned off, the nth MOSFET Mn is selected, and when the nth MOS switch SWn is turned on, the nth MOSFET Mn is not selected.

With reference to FIG. 1, the switching controller 400 generates first to nth control signals SC1 to SCn for controlling the first to nth MOS switches SW1 to SWn of the switching circuit unit 300, and provides the corresponding control signals to the first to nth MOS switches SW1 to SWn of the switching circuit unit 300, respectively.

Meanwhile, the main MOSFET M0 and the first to nth MOSFETs M1 to Mn are connected in series within the MOSFET circuit unit 200. The main MOSFET M0 may be directly connected to the first connection node N1, may be directly connected to a ground, or may be connected to the middle of the first to nth MOSFETs M1 to Mn.

For example, a structure in which the main MOSFET M0 is directly connected to the first connection node N1 will be described.

As shown in FIG. 1, the main MOSFET M0 may be configured as an N channel MOSFET having a drain connected to the first connection node N1, a gate receiving the bias voltage Vbias, and a source.

Here, the first to nth MOSFETs M1 to Mn may be connected in series between the source of the main MOSFET M0 and the ground, and the first to nth MOSFETs M1 to Mn may be configured as N channel MOSFETs, respectively.

In another example, a structure in which the main MOSFET M0 is directly connected to a ground will be described.

The first to nth MOSFETs M1 to Mn may be connected in series between the first connection node N1 and the main MOSFET M0, and may be configured as N Channel MOSFETs, respectively.

Here, the main MOSFET M0 may be configured as an N channel MOSFET having a drain connected to a source of the nth MOSFET Mn, a gate receiving the bias voltage Vbias, and a source connected to a ground.

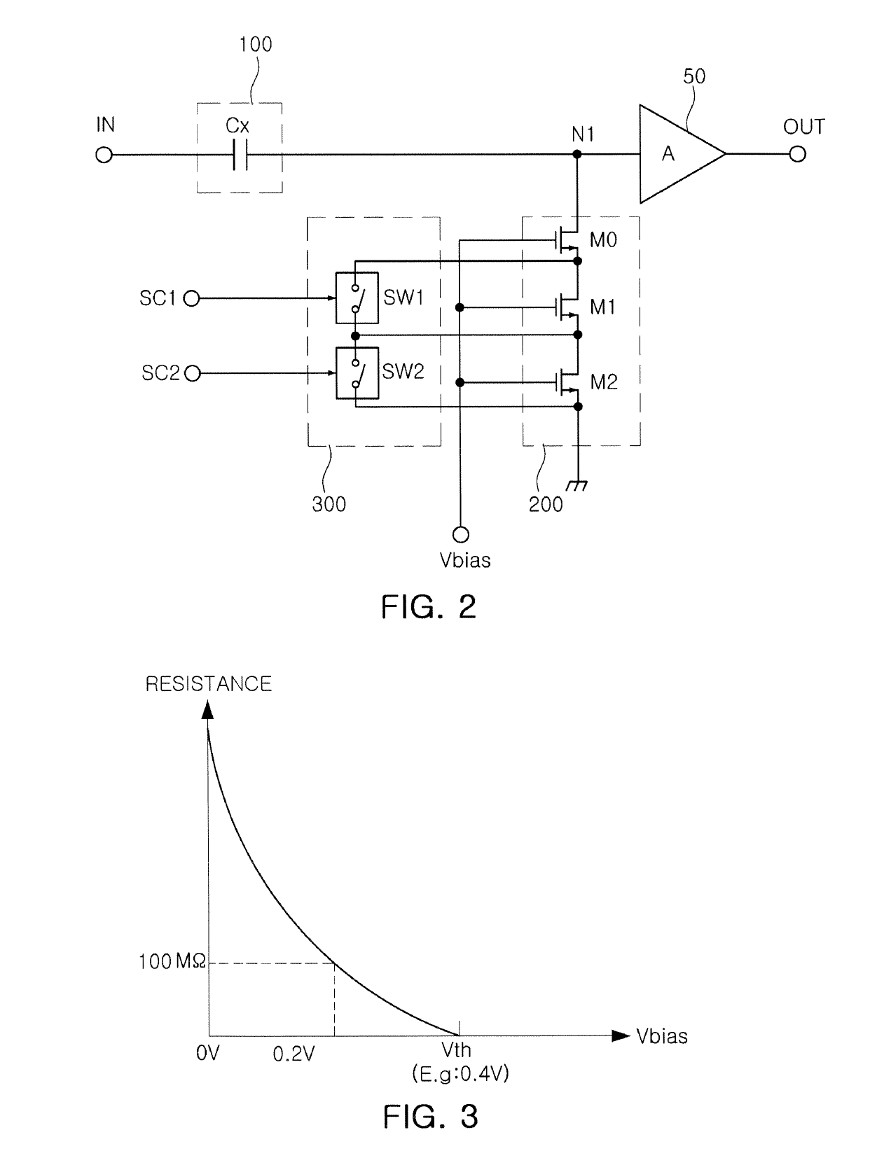

FIG. 2 is a view showing an implementation example of the DC offset cancellation circuit of FIG. 1.

With reference to FIG. 2, in an implementation example, the MOSFET circuit unit 200 may include the main MOSFET M0 and the first and second MOSFETs M1 and M2 connected in series between the first connection node N1 and a ground.

Here, the switching circuit unit 300 may include first and second MOS switches SW1 and SW2 for selecting the first and second MOSFETs M1 and M2 of the MOSFET circuit unit 200.

In this case, one of the first and second MOSFETs M1 and M2 within the MOSFET circuit unit 200, which is to be connected, may be determined according to an ON/OFF switching operation of the first and second MOS switches SW1 and SW2 of the switching circuit unit 300.

FIG. 3 an equivalent resistance graph of a MOSFET in a linear region in the DC offset cancellation circuit according to an embodiment of the present invention.

In the graph of FIG. 3, the horizontal axis is a bias voltage Vbias and the vertical axis is equivalent resistance of the MOSFET. With reference to the graph of FIG. 3, it is noted that a voltage smaller than a threshold voltage Vth and greater than 0V may be determined as the bias voltage Vbias in advance. For example, when the threshold value Vth is 0.4V, the bias voltage Vbias may be 0.2V, and in this case, as shown in FIG. 3, increased resistance of the single MOSFET may be 100 MΩ.

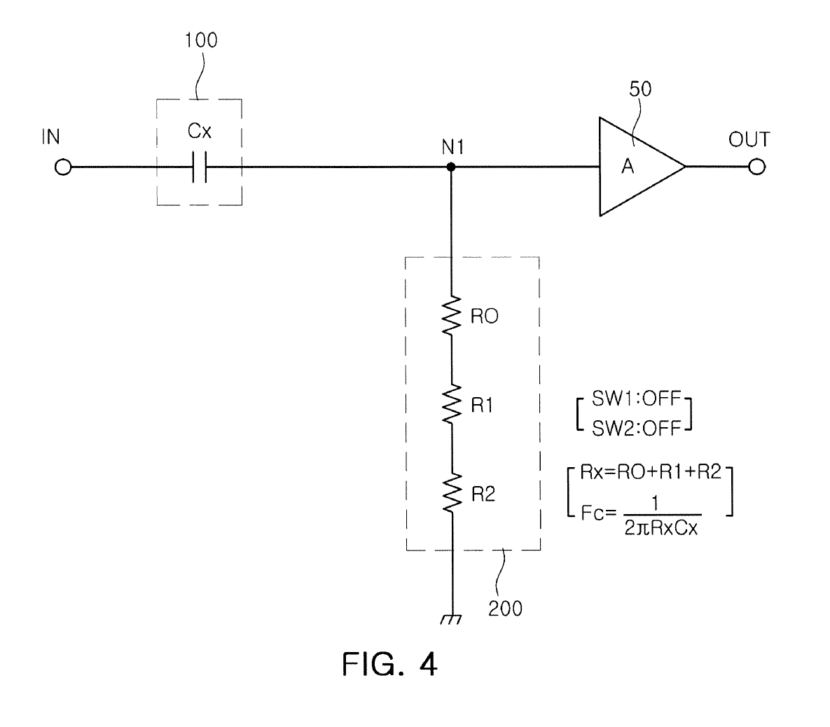

As described above, the number of the MOSFET to be connected to the first and second MOSFETs, among the first and second MOSFETs M1 and M2 within the MOSFET circuit unit 200, is determined according to the ON/OFF switching operation of the first and second MOS switches SW1 and SW2 of the switching circuit unit 300. This will be described with reference to FIGS. 4 through 6.

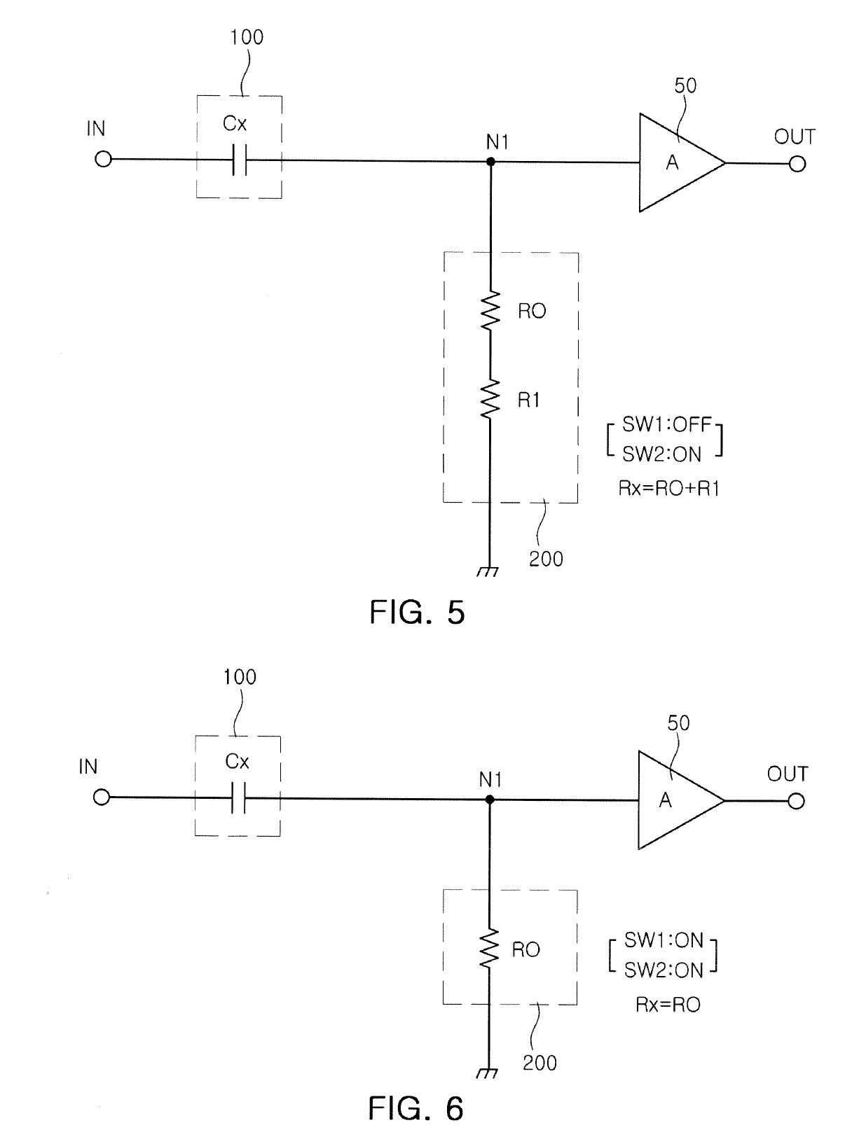

FIG. 4 is a view showing a first operation of the DC offset cancellation circuit of FIG. 2. FIG. 5 is a view showing a second operation of the DC offset cancellation circuit of FIG. 2. FIG. 6 is a view showing a third operation of the DC offset cancellation circuit of FIG. 2.

First, in FIG. 4, when both the first and second MOS switches SW1 and SW2 of the switching circuit unit 300 are turned off, both the first and second MOSFETs M1 and M2 are selected, and in this case, equivalent resistance Rx of the MOSFET circuit unit 200 is equivalent to resistance (Rx=R0+R1+R2) obtained by adding equivalent resistance R0 of the main MOSFET M0, equivalent resistance R1 of the first MOSFET M1, and equivalent R2 of the second MOSFET M2.

In FIG. 5, when the first MOS switch SW1, among the first and second MOS switches SW1 and SW2 of the switching circuit unit 300, is turned off and the second MOS switch SW2 is turned on, the first MOSFET m1 of the MOSFET circuit unit 200 is selected and the second MOSFET M2 is not selected. In this case, equivalent resistance Rx of the MOSFET circuit unit 200 is equivalent to resistance (Rx=R0+R1) obtained by adding the equivalent R0 of the main MOSFET M0 and the equivalent R1 of the first MOSFET M1.

In FIG. 6, when both the first and second MOS switches SW1 and SW2 of the switching circuit unit 300 are turned on, neither of the first and second MOSFETs M1 and M2 of the MOSFET circuit unit 200 is selected, and here, equivalent resistance Rx of the MOSFET circuit unit 200 is equivalent to equivalent resistance (R0=R1) of the main MOSFET M0.

In this manner, the MOSFETs to be connected, among the plurality of MOSFETs of the MOSFET circuit unit 200, may be selected according to the operation of the plurality of switch elements included in the switching circuit unit 300, and accordingly, the equivalent resistance Rx of the

MOSFET circuit unit 200 may be changed, and as a result, the cut-off frequency of the high pass filter including the capacitor circuit unit 100 and the MOSFET circuit unit 200 may be changed.

As set forth above, according to embodiments of the invention, the structure that can be applicable to a direct conversion receiver (DCR) system and includes the equivalent resistance of the triode region of the MOSFET, the capacitor, and the switch for selecting a frequency is proposed. The structure basically uses the HPF structure and the size of the capacitor or the resistor thereof is not required to be increased. The structure can be implemented as an integrated circuit by using the resistance in the linear region of the MOSFET and easily select a pass frequency.

While the present invention has been shown and described in connection with the embodiments, it will be apparent to those skilled in the art that modifications and variations can be made without departing from the spirit and scope of the invention as defined by the appended claims.

What is claimed is:

1. A DC offset cancellation circuit comprising:
a capacitor circuit unit including at least one capacitor connected between an input terminal and an input of an amplifier;
a metal-oxide-semiconductor field effect transistor (MOSFET) circuit unit including a plurality of MOSFETs connected in series between a first connection node connected to a predetermined one of both terminals of the capacitor circuit unit and a ground and operating in a linear region; and
a switching circuit unit including a plurality of switch elements for selecting several MOSFETs previously selected from among the plurality of MOSFETs of the MOSFET circuit unit, respectively.

2. The DC offset cancellation circuit of claim 1, wherein the MOSFET circuit unit comprises a main MOSFET and first to nth MOSFETs connected in series between the first connection node and the ground, and the main MOSFET and the first to nth MOSFET are set to operate in a linear region by a bias voltage.

3. The DC offset cancellation circuit of claim 2, wherein the switching circuit unit comprises first to nth MOS switches for selecting the first to nth MOSFETs of the MOSFET circuit unit, and each of the first to nth MOS switches is connected between a drain and a source of each of the first to nth MOSFETs.

4. The DC offset cancellation circuit of claim 2, wherein the main MOSFET is an N channel MOSFET having a drain connected to the first connection node, a gate receiving the bias voltage, and a source.

5. The DC offset cancellation circuit of claim 4, wherein the first to nth MOSFET are connected in series between the source of the main MOSFET and the ground, and the first to nth MOSFETs are N channel MOSFETs, respectively.

6. The DC offset cancellation circuit of claim 2, wherein the first to nth MOSFET are connected in series between the first connection node and the main MOSFET, and the first to nth MOSFETs are N channel MOSFETs, respectively.

7. The DC offset cancellation circuit of claim 6, wherein the main MOSFET is an N channel MOSFET having a drain connected to a source of the nth MOSFET, a gate receiving the bias voltage, and a source connected to the ground.

8. A DC offset cancellation circuit comprising:
a capacitor circuit unit including at least one capacitor connected between an input terminal and an input of an amplifier;
a MOSFET circuit unit including a plurality of MOSFETs connected in series between a first connection node connected to one of both terminals of the capacitor circuit unit and a ground and operating in a linear region;
a switching circuit unit including a plurality of switch elements for selecting several MOSFETs previously selected from among the plurality of MOSFETs of the MOSFET circuit unit, respectively; and
a switching controller controlling ON/OFF switching of the plurality of switch element of the switching circuit unit.

9. The DC offset cancellation circuit of claim 8, wherein the MOSFET circuit unit comprises a main MOSFET and first to nth MOSFETs connected in series between the first connection node and the ground, and the main MOSFET and the first to nth MOSFET are set to operate in a linear region by a bias voltage.

10. The DC offset cancellation circuit of claim 9, wherein the switching circuit unit comprises first to nth MOS switches for selecting the first to nth MOSFETs of the MOSFET circuit unit, and each of the first to nth MOS switches is connected between a drain and a source of each of the first to nth MOSFETs.

11. The DC offset cancellation circuit of claim 10, wherein the switching controller generates first to nth control signals for controlling the first to nth MOS switches of the switching circuit unit and provide the corresponding control signal to each of the first to nth MOS switches of the switching circuit unit.

12. The DC offset cancellation circuit of claim 9, wherein the main MOSFET is an N channel MOSFET having a drain connected to the first connection node, a gate receiving the bias voltage, and a source.

13. The DC offset cancellation circuit of claim 12, wherein the first to nth MOSFETs are connected in series between the source of the main MOSFET and the ground, and the first to nth MOSFETs are N channel MOSFETs, respectively.

14. The DC offset cancellation circuit of claim 9, wherein the first to nth MOSFETs are connected in series between the first connection node and the main MOSFET, and the first to nth MOSFETs are N channel MOSFETs, respectively.

15. The DC offset cancellation circuit of claim 14, wherein the main MOSFET is an N channel MOSFET having a drain connected to a source of the nth MOSFET, a gate receiving the bias voltage, and a source connected to a ground.
